(19) United States
(12) Patent Application Publication
(10) Pub. No.: US 2023/0354585 A1
(43) Pub. Date: Nov. 2, 2023

(54) DIGIT LINE AND CELL CONTACT ISOLATION

(71) Applicant: Micron Technology, Inc., Boise, ID (US)

(72) Inventors: Albert P. Chan, Boise, ID (US); Sanjeev Sapra, Boise, ID (US); Vivek Yadav, Boise, ID (US); Yen Ting Lin, Boise, ID (US); Devesh Dadhich Shreeram, Meridian, ID (US)

(21) Appl. No.: 17/731,895

(22) Filed: Apr. 28, 2022

(51) Int. Cl. H01L 27/108

(52) U.S. Cl. CPC H01L 27/10885; H01L 27/10814

(57) ABSTRACT

Methods, apparatuses, and systems related to a digit line and cell contact are described. An example apparatus includes a semiconductor structure comprising a first layer comprising a first material on sidewalls of a plurality of patterned material. The apparatus further includes a second layer comprising a nitride material on sidewalls of the first layer. The apparatus further includes a third layer comprising the first material on sidewalls of the second layer. The apparatus further includes a base area, to provide digit line and cell contact isolation for the semiconductor structure. The apparatus further includes an active area, adjacent to the base area, that is adjacent to the semiconductor structure.

### TECHNICAL FIELD

The present disclosure relates generally to semiconductor devices and methods, and more particularly to a digit line and cell contact isolation.

### BACKGROUND

Memory devices are typically provided as internal, semiconductor, integrated circuits in computers or other electronic devices. There are many different types of memory, including random-access memory (RAM), read only memory (ROM), dynamic random access memory (DRAM), static random access memory (SRAM), synchronous dynamic random access memory (SDRAM), ferroelectric random access memory (FeRAM), magnetic random access memory (MRAM), resistive random access memory (ReRAM), and flash memory, among others. Some types of memory devices may be non-volatile memory (e.g., ReRAM) and may be used for a wide range of electronic applications in need of high memory densities, high reliability, and low power consumption. Volatile memory cells (e.g., DRAM cells) require power to retain their stored data state (e.g., via a refresh process), as opposed to non-volatile memory cells (e.g., flash memory cells), which retain their stored state in the absence of power. However, various volatile memory cells, such as DRAM cells may be operated (e.g., programmed, read, erased, etc.) faster than various non-volatile memory cells, such as flash memory cells.

### BRIEF DESCRIPTION OF THE DRAWINGS

FIGS. 1A-4B illustrate cross-sectional views of a portion of a semiconductor structure of a memory device in association with a semiconductor fabrication sequence for removing a material using a wet etchant in accordance with a number of examples of the present disclosure.

FIG. 5 is a functional block diagram of a system in association with a semiconductor fabrication sequence for removing a material using a wet etchant process in accordance with a number of embodiments of the present disclosure.

FIG. 6 illustrates a functional block diagram of an apparatus in the form of a computing system including a semiconductor structure of a memory system in accordance with a number of embodiments of the present disclosure

### DETAILED DESCRIPTION

Various materials may be deposited using techniques such as chemical vapor deposition (CVD), plasma deposition, etc. The deposited materials can be patterned using techniques such photolithographic techniques and/or doping techniques and/or can be etched using wet and/or dry etch (e.g., vapor) processes to form semiconductor structures. Such semiconductor structures may contain, or be associated with, various materials that contribute to data access, storage, and/or processing, or to various support structures, on the memory device. As an example, a capacitor material may be deposited into an opening in a semiconductor structure to permit data access, storage, and/or processing use of the semiconductor structure including the capacitor material.

Dry etch processes are used in various memory device fabrication processes. For instance, a dry etch process can be employed to remove a portion of a material such as removing a portion of an insulator (spacer) material to expose material underlying the insulator layer. Such processes can be referred to in the art as ‘punch processes’ because the spacer material is punched through to expose the underlying material. However, dry etch processes can have various drawbacks. As scales continue to shrink, isolating digit line electrical contact can become prone to shorts. For instance, as scales grow smaller, spacer schemes have limitations like those due to nitride film continuity issues, cell contact hole issues. Punch processes employing a dry etchant can cause unintended surface damage to the underlying materials due at least in part to the dry etchant having low selectivity/affinity for different materials.

As a result, when punch processes employing a dry etchant are used, an unintended variation may occur in terms of depth, a shape, and/or other resultant aspects of an insulator material subjected to a punch process employing a dry etchant. For example, an insulating material subjected to punch processes employing a dry etchant may also exhibit undesired tapered profiles and/or exhibit spacer clipping (having over-etched undesired rounded edges.

To address the above and other shortcomings, a method employing a wet etchant and the resultant structure formed thereby is described herein. As an example, a semiconductor structure may be formed using a wet etchant that selectively etches a silicon oxycarbide (SiOC) material, rather than use of punch processes employing a dry etchant. Thus, the method employs the wet etchant and the resultant structures formed thereby avoid or mitigate any negative effects associated with a dry etch process, listed above.

An example method includes depositing a first layer formed of a first material on a patterned material. The method further includes subjecting the first layer to a plasma to expose horizontal portions of the first layer to the plasma. The method further includes subsequent to subjecting the first layer to the plasma, depositing a second layer formed of a nitride material on the first layer. The method further includes depositing a third layer formed of the first material on the second layer. The method further includes selectively removing at least a portion of the second layer with a wet etchant. The methods described herein may be used to form various devices. As such, the methods may be used as desired to form an apparatus.

In the following detailed description of the present disclosure, reference is made to the accompanying drawings that form a part hereof, and in which is shown by way of illustration how one or more examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure. As used herein, “a number of” something can refer to one or more such things. For example, a number of capacitors can refer to at least one capacitor.

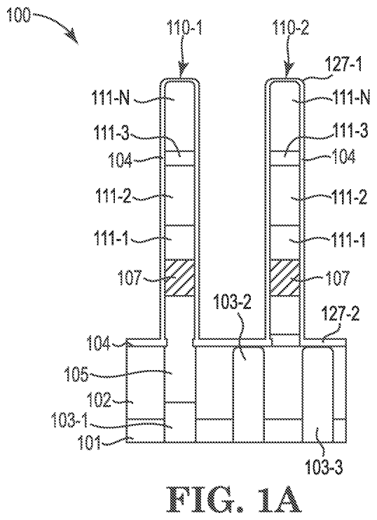

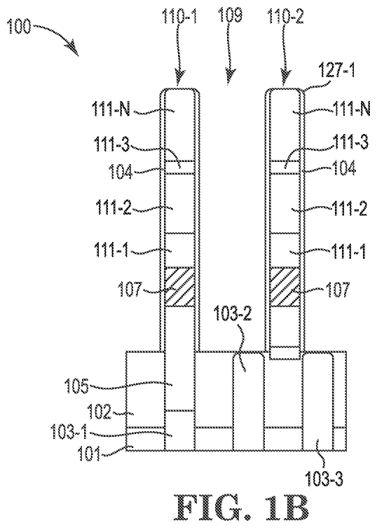

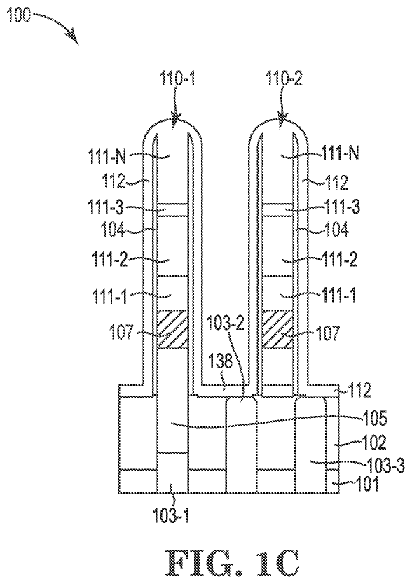

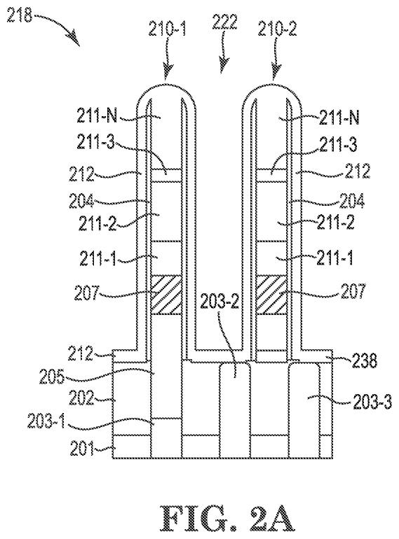

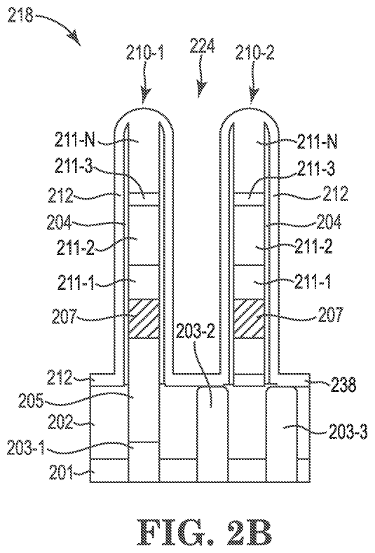

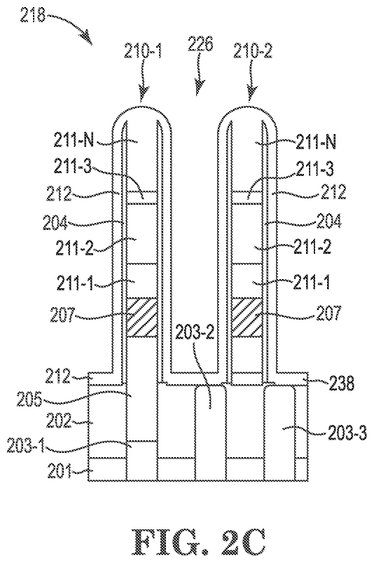

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1A, and a similar element may be referenced as 203 in FIG. 2A. In some instances, a plurality of similar, but functionally and/or structurally distinguishable, elements or components in the same figure or in different figures may be referenced sequentially with the same element number (e.g., 103-1, 103-2, 103-3 in FIG. 1A).

FIG. 1A illustrates a cross-sectional view 100 of a portion of a semiconductor structure of a memory device in association with a semiconductor fabrication sequence for removing a material using a wet etchant in accordance with a number of examples of the present disclosure. The example memory device can include a plurality of pattern of materials 110-1, 110-2 (hereinafter referred to collectively as pattern of materials 110). Each of the plurality of pattern of materials 110 may include a silicon active area 103 (individually referring to silicon active area 103-1, silicon active area 103-2 and silicon active area 103-3), a titanium nitride material 105, digit line 107 and layers of nitride material 111-1, 111-2, 111-3, . . . , 111-N (hereinafter referred to collectively as nitride materials 111). The digit line 107 may serve as a conductive material, titanium nitride material 105 may serve as a gate material, silicon active area 103 may serve as a source/drain region while nitride material 111 may serve as isolation materials for the plurality of pattern of materials 110. The pattern of materials 110 is surrounded by at its base by nitride material 102 and oxide material 101.

A first layer spacer material may be formed (e.g., deposited) on pattern of materials 110. The first layer 104 may be comprised of a silicon oxycarbide (SiOC). The silicon oxycarbide (SiOC) of the first layer 104 may be deposited around the pattern of materials 110. The oxide material of the first layer 104 may be a material having a lower dielectric constant (low-k) than other dielectric materials. The material may be selected for its dielectric properties. As used herein, the term “dielectric material” means and includes an electrically insulative material. The dielectric material may include, but is not limited to, one or more of an insulative oxide material or an insulative nitride material. A dielectric nitride may include, but is not limited to, boron nitride (BN), silicon nitride (SiNₓ, Si₃N₄), aluminum nitride (AlN), gallium nitride (GN), tantalum nitride (TaN, Ta₂N), titanium nitride (TiN, Ti₂N), and tungsten nitride (WN, W₂N, WN₂), among other possibilities, for formation of the nitride material. However, embodiments of the present disclosure are not limited to this example.

FIG. 1B illustrates a cross-sectional view 100 of a portion of a semiconductor structure of a memory device in association with a semiconductor fabrication sequence for removing a material using a wet etchant in accordance with a number of examples of the present disclosure. FIG. 1B illustrates the example semiconductor structure at a particular stage following completion of the example fabrication sequence described in connection with FIG. 1A.

The first layer 104 may be subjected to a plasma (as represented by element identifier 109) to expose horizontal portions (e.g., 127-1 and/or 127-2 in FIG. 1A) of the first layer 104 to the plasma 109. For instance, the first layer 104 may be subject to the plasma 109 to damage the horizontal portions, as illustrated by the sequence of FIG. 1A and FIG. 1B. That is, the plasma 109 may be formed an oxygen plasma or other type of plasma to selectively damage the first layer 104 such as at the horizontal portions (e.g., 127-1 and 127-2). In some embodiments, the plasma 109 can be a reducing plasma such as an O2/hydrogen gas (H2)/nitrogen gas (N2) or an O2/fluorocarbon plasma. The plasma 109 may also include an inert gas such as argon. Process conditions for the plasma treatment may be chosen depending on the composition of the plasma utilized for the process.

FIG. 1C illustrates a cross-sectional view 100 of a portion of a semiconductor structure of a memory device in association with a semiconductor fabrication sequence for removing a SiOC material using a wet etchant in accordance with a number of examples of the present disclosure. FIG. 1C illustrates the example semiconductor structure at a particular stage following completion of the example fabrication sequence described in connection with FIG. 1B.

An acid such as a hydrofluoric acid (e.g., a dilute hydrofluoric acid solution) can be used to remove the portions of the first layer 109 that are exposed to the plasma. Process conditions for the acid treatment may be chosen depending on the composition of the acid utilized for the process. For instance, hydrofluoric acid may be diluted with water at a ratio between 100 to 2500 parts water to 1 part hydrofluoric acid to form a suitable dilute hydrofluoric acid solution. The acid may selectively target the horizontal portions (e.g., 127-1 and 127-2) of the first layer 104.

Subsequent to subjecting the first layer 104 to the plasma 109 and then subsequently to the acid, a second layer spacer material may be formed (e.g., deposited) over the first layer 104. The second layer 112 may be comprised of a nitride material. The nitride material of the second layer 112 may be a different nitride material from the material of the first layer 104. The nitride material of the second layer 112 may be deposited around (e.g., conformally around) the first layer 104. The nitride material of the second layer 112 may include horizontal portions 138 deposited in spaces where the horizontal portions (e.g., 127-1 and 127-2) of the first layer 104 were situated prior to being etched away. The nitride material of second layer 112 may be formed from a nitride material selected for dielectric properties. For example, one or more dielectric and/or resistor nitrides may be selected from boron nitride (BN), silicon nitride (SiN_{X}, Si₃N₄), aluminum nitride (AlN), gallium nitride (GN), tantalum nitride (TaN, Ta₂N), titanium nitride (TiN, Ti₂N), and tungsten nitride (WN, W₂N, WN₂), among other possibilities, for formation of the nitride material of the second layer 112.

FIG. 2A illustrates a cross-sectional view 211 of a portion of a semiconductor structure of a memory device in association with a semiconductor fabrication sequence for removing a material using a wet etchant in accordance with a number of examples of the present disclosure. FIG. 2A illustrates the example semiconductor structure at a particular stage following completion of the example fabrication sequence described in connection with FIGS. 1A-1C.

The cross-sectional view 218 may include the same or similar elements as the example cross-sectional view 100 as referenced in FIG. 1C. For example, the pattern of materials 210 is analogous or similar to pattern of materials 110. Silicon active area 203 (individually referring to silicon active area 203-1, silicon active area 203-2, and silicon active area 203-3) may be analogous or similar to silicon active area 103. Titanium nitride material 205 may be analogous or similar to titanium nitride material 105. Digit line material 207 may be analogous or similar to digit line material 107. Nitride materials 211 may be analogous or similar to nitride materials 111. Oxide material 201 may be analogous or similar to oxide material 101. Nitride material 202 may be analogous or similar to nitride material 102. First layer 204 may be analogous or similar to first layer 104. Second layer 212 may be analogous or similar to second layer 112. The horizontal portions 238 of the second layer may be analogous or similar to the horizontal portions 138 of the second layer 112.

Subsequent to depositing the second layer 212 on the first layer 204, processing steps (as represented by element identifier 222) may be implemented on the pattern of materials 210 (which includes the plurality of pattern of materials 210-1, 210-2). The processing steps 222 may first include depositing a sacrificial fill material on a portion of the second layer 212. The sacrificial fill material may be deposited on the entirety of the second layer 212. The sacrificial fill material may be formed from an oxide material. The sacrificial fill material may also be formed from a carbon-based material. In some examples, the sacrificial fill material may be a spin-on dielectric (SOD). In other examples, the sacrificial fill dielectric material may be a spin-on carbon (SOC). As used herein, the term “sacrificial fill material” means and includes an electrically insulative material. The sacrificial fill material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ), doped SiOₓ, phosphosilicate glass, borosilicate glass, borophosphosilicate glass, fluorosilicate glass, tetraethylorthosilicate (TEOS), aluminum oxide (AlOₓ), gadolinium oxide (GdOx), hafnium oxide (HfOx), magnesium oxide (MgOx), niobium oxide (NbOx), tantalum oxide (TaOx), titanium oxide (TiOx), zirconium oxide carboxynitride material (e.g., SiOxCzNy), a combination thereof or a combination of one or more of the listed materials with silicon oxide.

Processing steps 222 subsequently includes forming (e.g., depositing) a silicate material over the dielectric material and a portion of the second layer 212. For example, the silicate layer may be formed over the oxide material and a portion of the nitride material. The silicate material 206 may, in a number of examples, be formed from tetraethyl orthosilicate (Si(OC₂H₅)₄), which is also referred to as TEOS. TEOS may be formed as an ethyl ester of orthosilicic acid (Si(OH)₄), among other possibilities. The silicate material 206 may, in a number of examples, have been formed from borophosphosilicate glass (BPSG). The BPSG may include a silicon compound doped with various concentrations and/or ratios of a boron compound and a phosphorus compound. The silicon compound may be silicon dioxide (SiO2), which may be formed by oxidation of silane (SiH4), among other possibilities. The boron compound may be diboron trioxide (B2O3), which may be formed by oxidation of diborane (B2H6), among other possibilities. The phosphorus compound may be diphosphorus pentoxide (P2O5), which may be formed by oxidation of phosphine (PH3), among other possibilities. The silicon, boron, and phosphorus compounds of the BPSG may include various isotopes of silicon, boron, and phosphorus, as determined to be appropriate for functionality, and/or formation of the silicate material 206, as described herein.

FIG. 2B illustrates a cross-sectional view 218 of a portion of a semiconductor structure of a memory device in association with a semiconductor fabrication sequence for removing a nitride material using a wet etchant in accordance with a number of examples of the present disclosure. FIG. 2B illustrates the example semiconductor structure at a particular stage following completion of the example fabrication sequence described in connection with FIG. 2A.

Subsequent to depositing a silicate material over the dielectric material and a portion of the second layer 212, processing steps (as represented by element identifier 224) may be implemented on the pattern of materials 210. The processing steps 224 may first include depositing a second nitride material. In one example, the second nitride material of processing steps 224 may be formed from the same material as the nitride material within second layer 212. The second nitride material of processing steps 224 may be formed from a nitride material selected for dielectric properties. The second nitride material of processing steps 224 may be selected for its dielectric properties. For example, one or more dielectric and/or resistor nitrides may be selected from boron nitride (BN), silicon nitride (SiNₓ, Si₃N₄), aluminum nitride (AlN), gallium nitride (GN), tantalum nitride (TaN, Ta₂N), titanium nitride (TiN, Ti₂N), and tungsten nitride (WN, W₂N, WN₂), among other possibilities, for formation of the nitride material. However, embodiments of the present disclosure are not limited to this example.

FIG. 2C illustrates a cross-sectional view 218 of a portion of a semiconductor structure of a memory device in association with a semiconductor fabrication sequence for removing a material using a wet etchant in accordance with a number of examples of the present disclosure. FIG. 2C illustrates the example semiconductor structure at a particular stage following completion of the example fabrication sequence described in connection with FIG. 2B.

A wet etchant (as represented by element identifier 226) may be deposited on the pattern of materials 210 to selectively remove portions of the dielectric material and the silicate material. For example, the wet etchant 226 may be deposited to etch away the dielectric material and the silicate material. The wet etchant 226 may be carried out using a dilute hydrofluoric (HF) acid combination. For example, the dilute HF acid combination may include ammonium fluoride (NH₄F) as well as other additives. The HF may be diluted with water at a ratio between 10 to 2500 parts water to 1 part hydrofluoric acid. The HF may selectively target the dielectric material, absent etching the nitride materials.

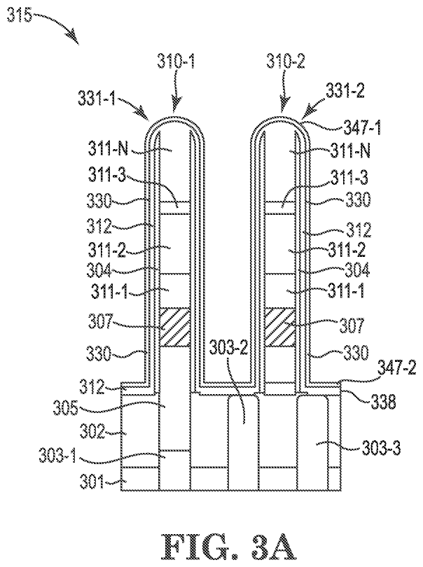

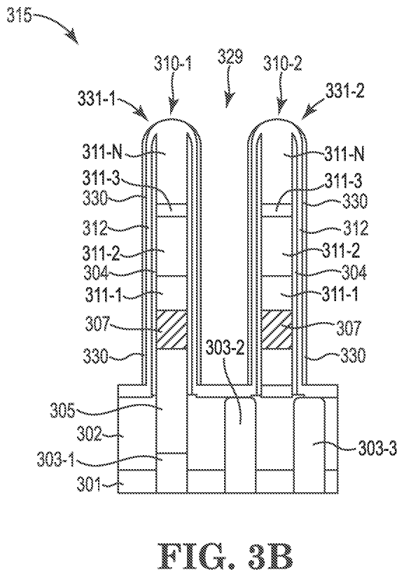

FIG. 3A illustrates a cross-sectional view 315 of a portion of a semiconductor structure (e.g., semiconductor structure 331-1) of a memory device in association with a semiconductor fabrication sequence for removing a material using a wet etchant in accordance with a number of examples of the present disclosure. FIG. 3A illustrates the example semiconductor structure following completion of the example fabrication sequence described in connection with FIGS. 2A-2C.

The cross-sectional view 315 can include the same or similar elements as the example cross-sectional view 100 and 218 as referenced in FIGS. 1 and 2, respectively. For example, the pattern of materials 310 is analogous or similar to pattern of materials 110 and 210, respectively. Silicon active area 303 (individually referring to silicon active area 303-1, silicon active area 303-2, and silicon active area 303-3) may be analogous or similar to silicon active area 103 and 203. Titanium nitride material 305 may be analogous or similar to titanium nitride material 105 and 205. Digit line material 307 may be analogous or similar to digit line material 107 and 207. Nitride materials 311 may be analogous or similar to nitride materials 111 and 211. Oxide material 301 may be analogous or similar to oxide material 101 and 201. Nitride material 302 may be analogous or similar to nitride material 102 and 202. First layer 304 may be analogous or similar to first layer 104 and 204. Second layer 312 may be analogous or similar to second layer 112 and 212.

Subsequent to the wet etchant, a third layer spacer material may be formed (e.g., deposited) on the second layer 312. The third layer 330 may serve as a liner material to protect the second layer. The third layer 330 may be comprised of a silicon oxycarbide (SiOC) material. The third layer 330 may be deposited around the nitride material of the second layer 312. The material of the third layer 330 may be a material having a lower dielectric constant (low-k) than other dielectric materials. The material may be selected for its dielectric properties. The material of the third layer 330 may be formed from a similar material to the material of the first layer 304. As such, the material of the third layer 330 may be a different material from the material of the second layer 312. Formation of third layer 330 may complete formation of a semiconductor structure (e.g., 331-1 and 331-2 hereinafter referred to collectively as semiconductor structure 331). A semiconductor structure 331 may include the first layer 304, with its horizontal portions etched away, the second layer 312, and the third layer 330.

FIG. 3B illustrates a cross-sectional view 315 of a portion of a semiconductor structure of a memory device in association with a semiconductor fabrication sequence for removing a material using a wet etchant in accordance with a number of examples of the present disclosure. FIG. 3B illustrates the example semiconductor structure at a particular stage following completion of the example fabrication sequence described in connection with FIG. 3A.

The third layer 330 may be subjected to a plasma material (as represented by element identifier 329) to expose horizontal portions (e.g., 347-1 and 347-2) of the third layer 330 to the plasma 329. The plasma 329 may be formed from a similar material to the plasma used to etch the first layer 304 (e.g., as described in FIG. 1A). The plasma and subsequent acid (e.g., a dilute HF acid solution) may selectively target the horizontal portions (e.g., 347-1 and 347-2) of the third layer 330 at the top (e.g., 347-1) of the pattern of materials 310 (which includes the plurality of pattern of materials 310-1, 310-2) and also right above nitride material 305 absent etching the second layer 312. For example, the plasma 329 may damage the horizontal portions (e.g., 347-1 and 347-2) of the nitride material of the third layer 330 but not the horizontal portion 338 of the nitride material of the second layer 312.

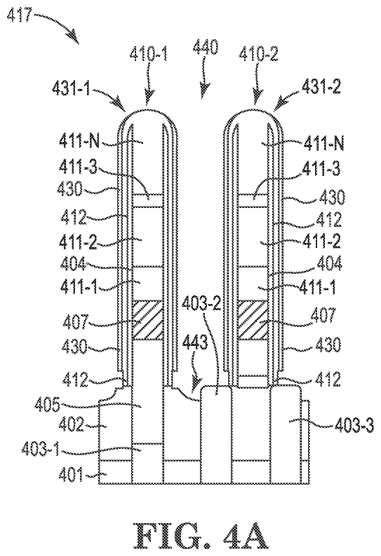

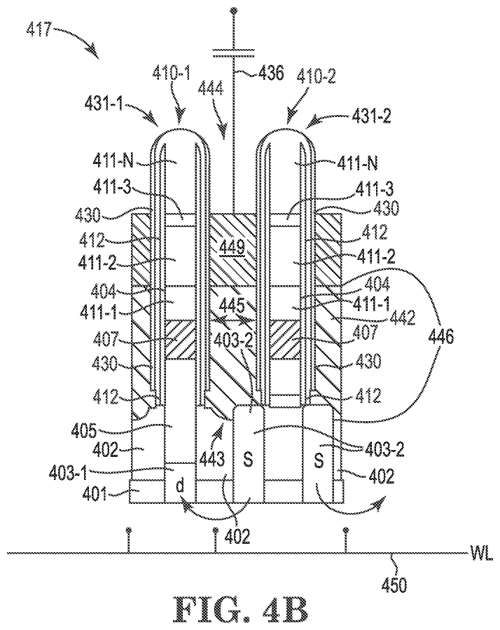

FIG. 4A illustrates a cross-sectional view 417 of a portion of a semiconductor structure of a memory device in association with a semiconductor fabrication sequence for removing a material using a wet etchant in accordance with a number of examples of the present disclosure. FIG. 4A illustrates the example semiconductor structure following completion of the example fabrication sequence described in connection with FIGS. 3A-3B.

The cross-sectional view 417 can include the same or similar elements as the example cross-sectional views 100, 218, and 315 as referenced in FIGS. 1, 2, and 3 respectively. For example, the pattern of materials 410 is analogous or similar to pattern of materials 110, 210, and 310 as referenced in FIGS. 1, 2, and 3 respectively. Silicon active area 403 (individually referring to silicon active area 403-1, silicon active area 403-2, and silicon active area 403-3) may be analogous or similar to silicon active area 103, 203, and 303 as referenced in FIGS. 1, 2, and 3 respectively. Titanium nitride material 405 may be analogous or similar to titanium nitride material 105, 205, and 305 as referenced in FIGS. 1, 2, and 3 respectively. Digit line material 407 may be analogous or similar to digit line material 107, 207, and 307 as referenced in FIGS. 1, 2, and 3 respectively.

Nitride materials 411 may be analogous or similar to nitride materials 111, 211, and 311 as referenced in FIGS. 1, 2, and 3 respectively. Oxide material 401 may be analogous or similar to oxide material 101, 201, and 301 as referenced in FIGS. 1, 2, and 3 respectively. Nitride material 402 may be analogous or similar to nitride material 102, 202, and 302 as referenced in FIGS. 1, 2, and 3 respectively. First layer 404 may be analogous or similar to first layer 104, 204, and 304 as referenced in FIGS. 1, 2, and 3 respectively. Second layer 412 may be analogous or similar to second layer 112, 212, and 312 as referenced in FIGS. 1, 2, and 3 respectively. Third layer 430 may be analogous or similar to third layer 130, 230, and 330 as referenced in FIGS. 1, 2, and 3 respectively.

A wet etchant (as represented by element identifier 440) may be used to remove the portions of the second layer 412 and portions of the nitride material 402. The wet etchant 440 may be used to remove the horizontal portions of the second layer 412. The wet etchant 440 may expose silicon active area 403-2 in the process of removing portions of the second layer 412 and portions of the nitride material 402. The wet etchant 440 may be an isotropic solution to target nitride materials. For example, the wet etchant 440 may selectively target the nitride material of the second layer 412 and portions of the nitride material 402 absent etching the silicon material within the silicon active area 403-2. The wet etchant's 440 removal of a portion of nitride material 402 may create a base area 443. The base area may be curved. Base area 443 desirably has a curved shape as a result of using a wet etchant 440. Conversely, a dry etch may etch away portions of silicon active area 403-2 along with portions of nitride material 402.

The wet etchant 440 may be carried out using a dilute hydrofluoric (HF) acid combination or a phosphoric acid solution. The HF acid may be diluted with water at a ratio between 500 to 2500 parts water to 1 part hydrofluoric acid. The HF acid may selectively target the nitride material of the second layer 412 and portions of the nitride material 402 absent etching the silicon material within the silicon active area 403-2. The phosphoric acid solution may be an elevated temperature having a temperature ranging from 100 to 160 degrees Celsius (° C.). The wet etchant 440 may be utilized to complete the semiconductor fabrication sequence absent a dry etch. The methods described herein may be used in the absence of a dry etchant.

FIG. 4B illustrates a cross-sectional view 417 of a portion of a semiconductor structure of a memory device in association with a semiconductor fabrication sequence for removing a material using a wet etchant in accordance with a number of examples of the present disclosure. FIG. 4B illustrates the example semiconductor structure at a particular stage following completion of the example fabrication sequence described in connection with FIG. 4A.

A polysilicon material 442 may be deposited on the sidewalls of the pattern of materials 410. For example, the polysilicon material 442 may be deposited in the spaces between the pattern of materials 410. Subsequent to the deposition of the polysilicon material 442, the polysilicon material 442 may be subjected to a planarization process. In one example, CMP may be used to planarize the polysilicon material 442. In another example, a Tetramethylammonium hydroxide (TMAH) solution may be used to planarize the polysilicon material 442. TMAH is a quaternary ammonium salt that is commonly encountered in form of concentrated solutions in water or methanol. The planarization may cause minimal overburden for the polysilicon material 442.

In one example, subsequent to the planarization, the polysilicon material 442 may be further subjected to a rapid thermal processing (RTP) to further trim the polysilicon material 442. RTP is a process used in semiconductor device fabrication which involves heating a single silicon wafer at a time to temperatures exceeding 1,000° C. for a few seconds in order to affect its electrical properties. The RTP process aids the polysilicon in avoiding voids during the planarization process. In another example, the polysilicon material 442 may be subjected to a vapor etchant (as represented by element identifier 444) to further recess the polysilicon material 442. The vapor etchant 444 may be formed from an oxide material. The vapor etchant 444 may remove portions of the polysilicon material 442 absent etching the nitride material of the third layer 430. The vapor etchant 444 may assist in preservation of the third layer 430. After the recess, the polysilicon material may fill a portion of an amount of space 445 between two semiconductor structures (e.g., 431-1 and 431-2). The space 445 may have a height 446 between the two semiconductor structures (e.g., 431-1 and 431-2).

Subsequent to the planarization and recess of the polysilicon material 442, a conductive material 449 may be deposited on the polysilicon material 442. Conductive material 449 may be a metal material. For example, conductive material 449 may be a tungsten (W) material or a titanium nitride (TiN) material. The conductive material 449 may be deposited on a top surface the polysilicon material 442, as illustrated in FIG. 4B. The polysilicon material 442 may serve as a conductive contact and aids connectivity between the conductive material 449, the base area 443, and/or the digit line material 407. A colbalt silicide (CoSi) may be formed at the intersection of conductive material 449 and polysilicon material 442 to aid in conductivity. The process described above may provide digit line and cell contact isolation for the semiconductor structures (e.g., 431-1 and 431-2) and may provide better digit line capacitance. As shown in FIG. 4B, a capacitor schematic 436 may be shown. A storage node may be connected to the source region, which is connected to the drain region and both are connected to the passing word line 450.

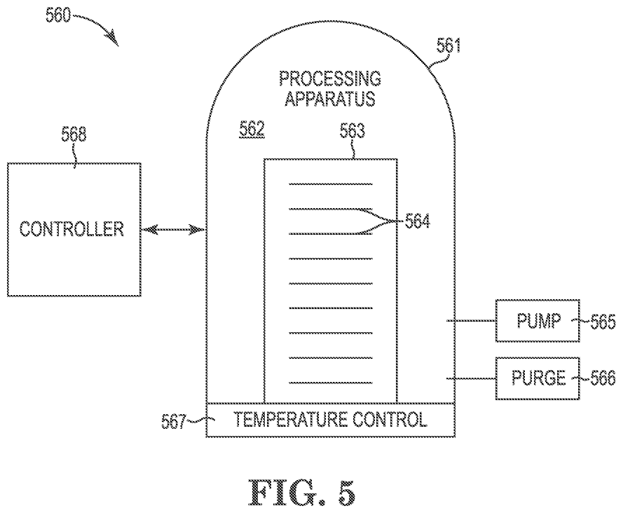

FIG. 5 is a functional block diagram of a system 560 for implementation of an example semiconductor fabrication process in accordance with a number of embodiments of the present disclosure. The system 560 can include a processing apparatus 561. The processing apparatus 561 can be configured to enable stacking a semiconductor structure.

The processing apparatus 561 can include a semiconductor processing chamber 562 to enclose components configured to stack a semiconductor structure. The semiconductor processing chamber 562 can further enclose a carrier 563 to hold a batch of semiconductor wafers 564. The processing apparatus 561 can include and/or be associated with tools including, for example, a pump 565 unit and a purge 566 unit configured to introduce and remove reducing agents. The processing apparatus 561 can further include a temperature control 567 unit configured to maintain the chamber 562 at appropriate temperatures as described herein.

The system 560 can further include a controller 568. The controller 568 can include, or be associated with, circuitry and/or programming for implementation of, for instance, stacking a semiconductor structure. Adjustment of such deposition and purging operations by the controller 568 can control the thickness of the materials described herein (such as the first material and the second material).

The controller 568 can, in a number of embodiments, be configured to use hardware as control circuitry. Such control circuitry may, for example, be an application specific integrated circuit (ASIC) with logic to control fabrication steps, via associated deposition and purge processes.

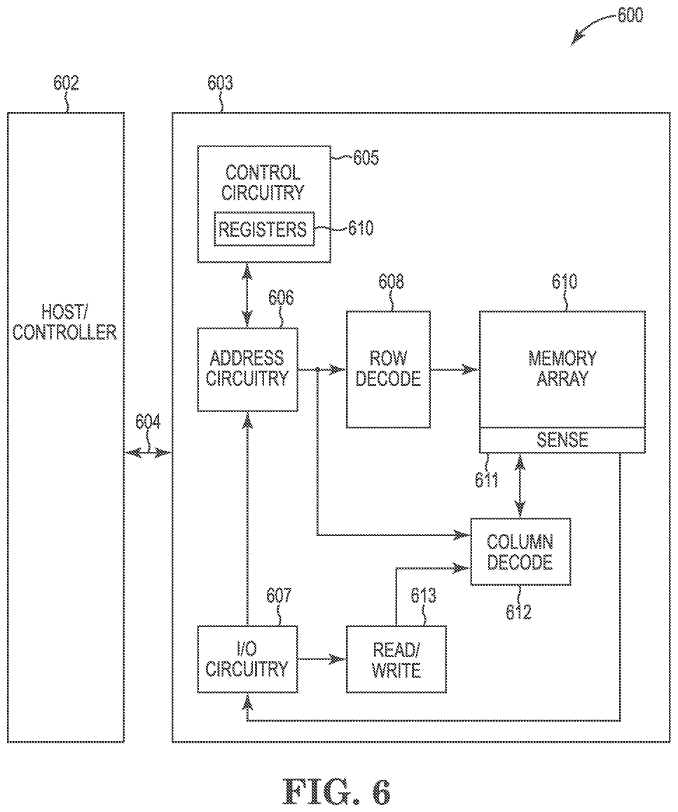

FIG. 6 is a block diagram of an apparatus in the form of a computing system 600 including a memory device 633 in accordance with a number of embodiments of the present disclosure. As used herein, a memory device 633, a memory array 614, and/or a host 632, for example, might also be separately considered an “apparatus.” According to embodiments, the memory device 632 may comprise at least one memory array 614 with a memory cell formed having a digit line and body contact, according to the embodiments described herein.

In this example, system 600 includes a host 632 coupled to memory device 633 via an interface 634. The computing system 600 can be a personal laptop computer, a desktop computer, a digital camera, a mobile telephone, a memory card reader, or an Internet-of-Things (IoT) enabled device, among various other types of systems. Host 632 can include a number of processing resources (e.g., one or more processors, microprocessors, or some other type of controlling circuitry) capable of accessing memory 633. The system 600 can include separate integrated circuits, or both the host 632 and the memory device 633 can be on the same integrated circuit. For example, the host 632 may be a system controller of a memory system comprising multiple memory devices 633, with the system controller 635 providing access to the respective memory devices 633 by another processing resource such as a central processing unit (CPU).

In the example shown in FIG. 6, the host 632 is responsible for executing an operating system (OS) and/or various applications (e.g., processes) that can be loaded thereto (e.g., from memory device 633 via controller 635). The OS and/or various applications can be loaded from the memory device 633 by providing access commands from the host 632 to the memory device 633 to access the data comprising the OS and/or the various applications. The host 632 can also access data utilized by the OS and/or various applications by providing access commands to the memory device 633 to retrieve said data utilized in the execution of the OS and/or the various applications.

For clarity, the system 600 has been simplified to focus on features with particular relevance to the present disclosure. The memory array 614 can be a DRAM array comprising at least one memory cell having a digit line and body contact formed according to the techniques described herein. For example, the memory array 614 can be a 4F² array. The array 614 can comprise memory cells arranged in columns coupled by word lines (which may be referred to herein as access lines or select lines) and rows coupled by digit lines (which may be referred to herein as sense lines or data lines). Although a single array 614 is shown in FIG. 6, embodiments are not so limited. For instance, memory device 633 may include a number of arrays 614 (e.g., a number of banks of DRAM cells).

The memory device 633 includes address circuitry 616 to latch address signals provided over an interface 634. The interface can include, for example, a physical interface employing a suitable protocol (e.g., a data bus, an address bus, and a command bus, or a combined data/address/command bus). Such protocol may be custom or proprietary, or the interface 634 may employ a standardized protocol, such as Peripheral Component Interconnect Express (PCIe), Gen-Z, CCIX, or the like. Address signals are received and decoded by a row decoder 608 and a column decoder 623 to access the memory array 614. Data can be read from memory array 614 by sensing voltage and/or current changes on the sense lines using sensing circuitry 621. The sensing circuitry 621 can comprise, for example, sense amplifiers that can read and latch a page (e.g., row) of data from the memory array 614. The I/O circuitry 637 can be used for bi-directional data communication with the host 632 over the interface 634. The read/write circuitry 613 is used to write data to the memory array 614 or read data from the memory array 614. As an example, the circuitry 613 can comprise various drivers, latch circuitry, etc.

Control circuitry 635 decodes signals provided by the host 632. The signals can be commands provided by the host 632. These signals can include chip enable signals, write enable signals, and address latch signals that are used to control operations performed on the memory array 614, including data read operations, data write operations, and data erase operations. In various embodiments, the control circuitry 635 is responsible for executing instructions from the host 632. The control circuitry 635 can comprise a state machine, registers 620, a sequencer, and/or some other type of control circuitry, which may be implemented in the form of hardware, firmware, or software, or any combination of the three. In some examples, the host 632 can be a controller external to the memory device 633. For example, the host 632 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

In the above detailed description of the present disclosure, reference is made to the accompanying drawings that form a part hereof, and in which is shown by way of illustration how one or more examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

It is to be understood that the terminology used herein is for the purpose of describing particular examples only and is not intended to be limiting. As used herein, the singular forms “a”, “an”, and “the” include singular and plural referents, unless the context clearly dictates otherwise, as do “a number of”, “at least one”, and “one or more” (e.g., a number of memory arrays may refer to one or more memory arrays), whereas a “plurality of” is intended to refer to more than one of such things. Furthermore, the words “can” and “may” are used throughout this application in a permissive sense (i.e., having the potential to, being able to), not in a mandatory sense (i.e., must). The term “include,” and derivations thereof, means “including, but not limited to”. The terms “coupled” and “coupling” mean to be directly or indirectly connected physically and, unless stated otherwise, can include a wireless connection for access to and/or for movement (transmission) of instructions (e.g., control signals, address signals, etc.) and data, as appropriate to the context.

While example examples including various combinations and configurations of semiconductor materials, underlying materials, structural materials, dielectric materials, capacitor materials, working surface materials, silicate materials, nitride materials, buffer materials, etch chemistries, etch processes, solvents, memory devices, memory cells, sidewalls of openings and/or trenches, among other materials and/or components related to stacking a semiconductor structure have been illustrated and described herein, examples of the present disclosure are not limited to those combinations explicitly recited herein. Other combinations and configurations of the semiconductor materials, underlying materials, structural materials, dielectric materials, capacitor materials, substrate materials, working surfaces, silicate materials, nitride materials, buffer materials, etch chemistries, etch processes, solvents, memory devices, memory cells, sidewalls of openings and/or trenches related to stacking a semiconductor structure than those disclosed herein are expressly included within the scope of this disclosure.

Although specific examples have been illustrated and described herein, those of ordinary skill in the art will appreciate that an arrangement calculated to achieve the same results may be substituted for the specific examples shown. This disclosure is intended to cover adaptations or variations of one or more examples of the present disclosure. It is to be understood that the above description has been made in an illustrative fashion, and not a restrictive one. Combination of the above examples, and other examples not specifically described herein will be apparent to those of skill in the art upon reviewing the above description. The scope of the one or more examples of the present disclosure includes other applications in which the above structures and processes are used. Therefore, the scope of one or more examples of the present disclosure should be determined with reference to the appended claims, along with the full range of equivalents to which such claims are entitled.

In the foregoing Detailed Description, some features are grouped together in an example for the purpose of streamlining the disclosure. This method of disclosure is not to be interpreted as reflecting an intention that the disclosed examples of the present disclosure have to use more features than are expressly recited in each claim. Rather, as the following claims reflect, inventive subject matter lies in less than all features of a disclosed example. Thus, the following claims are hereby incorporated into the Detailed Description, with each claim standing on its own as a separate example.

What is claimed is:

1. An apparatus, comprising:
a semiconductor structure comprising:
a first layer comprising a first material on sidewalls of a plurality of patterned material;
a second layer comprising a nitride material on sidewalls of the first layer; and
a third layer comprising the first material on sidewalls of the second layer;
a base area, adjacent the semiconductor structure; and
an active area, adjacent the base area, that is adjacent to the semiconductor structure.

2. The apparatus of claim 1, wherein the first material is a silicon oxycarbide (SiOC) material.

3. The apparatus of claim 1, wherein at least a portion of the active area is exposed between the semiconductor structures.

4. The apparatus of claim 3, wherein the SiOC material is a low-K material.

5. The apparatus of claim 1, wherein a polysilicon material connects a conductive material to the base area.

6. The apparatus of claim 1, wherein first layer is a planar first layer, wherein the second layer is a planar second layer, and wherein the third layer is a planar layer.

7. The apparatus of claim 1, wherein the first material and the second material are different materials.

8. An apparatus, comprising:
a semiconductor structure comprising:
a first layer comprising a silicon oxycarbide (SiOC) material on a plurality of patterned material;
a second layer comprising a nitride material, on the first material; and
a third layer comprising the SiOC material on the second material; and
a base area formed from an access line within the plurality of patterned material;
an active area between two semiconductor structures;
a polysilicon material on the sidewalls of the third layer; and
a conductive material on the polysilicon material.

9. The apparatus of claim 8, wherein the polysilicon material fills a portion of an amount of space between two semiconductor structure.

10. The apparatus of claim 8, wherein the polysilicon material is between the two semiconductor structures and is adjacent to the active area.

11. The apparatus of claim 8, wherein the active area is vertically oriented below the semiconductor structure and the polysilicon material.

12. The apparatus of claim 8, wherein the pattern of materials includes an oxide material, a digit line and a plurality of nitride materials.

13. The apparatus of claim 8, wherein a dielectric material is on the second layer.

14. The apparatus of claim 13, wherein the dielectric material is an oxide material.

15. A method of forming an apparatus, comprising:
depositing a first layer formed of a silicon oxycarbide (SiOC) material on a plurality of patterned material;
subjecting the SiOC material to an oxygen plasma to damage horizontal portions of the SiOC material;
selectively removing the horizontal portions of the SiOC material with a wet etch;
depositing a second layer formed of a nitride material on the first layer;
depositing a dielectric material on a portion of the nitride material;
depositing a silicate material on the dielectric material and a portion of the nitride material;
selectively removing portions of the dielectric material and the silicate material with a wet etchant;
depositing a third layer formed of a silicon oxycarbide (SiOC) material on the second layer;
subjecting the SiOC material of the third layer to an oxygen plasma to damage horizontal portions of the SiOC material;
selectively removing a portion of the second layer and at least a portion of the third layer with a wet etchant;
depositing a polysilicon material on the sidewalls of the plurality of patterned material; and
subjecting the polysilicon material to a vapor etchant to form the apparatus.

16. The method of claim 15, further comprising:
depositing the second layer on the first layer;
depositing the dielectric material on the second layer;
performing a chemical mechanical polishing (CMP) on the dielectric material;
depositing a silicate material on the dielectric material and a portion of the nitride material;
depositing a nitride material on the silicon material; and
selectively removing portions of the dielectric material and the silicate material with a wet etch.

17. The method of claim 15, further comprising forming the vapor etchant from an oxide material.

18. The method of claim 15, wherein subjecting the polysilicon material to a vapor etchant comprises selectively etching the polysilicon material in the absence of etching the SiOC material.

19. The method of claim 15, wherein the silicate material further comprises tetraethyl orthosilicate (Si(OC₂H₅)₄).

20. The method of claim 15, wherein the dielectric material further comprises a spin-on dielectric material (SOD) or a spin-on carbon (SOC).

21. The method of claim 15, further comprising forming the wet etchant from a hydrofluoric acid solution or phosphorus acid solution.
